(19) United States
(12) Patent Application Publication
(10) Pub. No.: US 2026/0092998 A1
(43) Pub. Date: Apr. 2, 2026

(54) Capturing Diffusion-Weighted Scan Data with Non-Trapezoidal Gradient Waveforms for Diffusion Encoding

(71) Applicant: Siemens Healthineers AG, Forchheim (DE)

(72) Inventor: Thorsten Feiweier, Poxdorf (DE)

(73) Assignee: Siemens Healthineers AG, Forchheim (DE)

(21) Appl. No.: 19/340,459

(22) Filed: Sep. 25, 2025

(30) Foreign Application Priority Data
Sep. 30, 2024 (DE) 10 2024 209 537.0

(51) Int. Cl. G01R 33/563; G01R 33/56

(52) U.S. Cl. CPC G01R 33/56341; G01R 33/5602; G01R 33/5608

(57) ABSTRACT

A method is disclosed for capturing diffusion-weighted scan data of an examination object with a magnetic resonance system using a scan protocol that includes a non-trapezoidal gradient waveform for diffusion encoding. The method comprises loading the scan protocol to be used with scan parameters to be set, including the non-trapezoidal waveform, and loading prepared characteristics of the waveform. Possible parameter values of at least one scan parameter are assigned to categories indicating executability of the protocol on the magnetic resonance system based on the loaded characteristics. At least one desired parameter value is then input taking into account the assignment. If values have not yet been input for all required parameters, the assigning and inputting steps are repeated until all parameters are set with values enabling execution of the protocol. Diffusion-weighted scan data are then captured using the scan protocol with the input parameter values.

### TECHNICAL FIELD

The disclosure relates to an improved capturing of diffusion-weighted scan data with non-trapezoidal gradient waveforms for diffusion encoding, in particular, taking account of limit values specified by a hardware unit of a magnetic resonance system that is used.

### BACKGROUND

Magnetic resonance technology (hereinafter, the abbreviation MR stands for magnetic resonance) is a known technology with which images of the interior of an examination object can be generated. Expressed simply, for this purpose, the examination object is positioned in a magnetic resonance device in a relatively strong, static, homogeneous main magnetic field, also known as the B0 field, with field strengths from 0.2 tesla to 7 tesla or more, so that its nuclear spins become oriented along the main magnetic field. In order to trigger nuclear spin resonances that are measurable as signals, high-frequency excitation pulses (RF pulses) are radiated into the examination object, and the nuclear spin resonances produced are measured as so-called k-space data by means of coils configured for receiving and, on the basis thereof, MR images are reconstructed or spectroscopic data is established. The alternating magnetic field created by the excitation pulse radiated in by way of the at least one transmitting coil is also known as the B1-field. For position encoding of the scan data, rapidly switched magnetic gradient fields, known as gradients for short, are overlaid on the main magnetic field. A temporal progression of a gradient field of this type, for example, in the direction of a gradient axis, can also be designated the gradient waveform. A scheme that is used, which defines a temporal sequence of RF pulses to be radiated and gradients to be switched, is known as a pulse sequence (scheme) or sequence for short. The recorded scan data is digitized and stored as complex number values in a k-space matrix. From the k-space matrix populated with values, an associated MR image can be reconstructed, for example, by means of a multidimensional Fourier transform.

Usually, a magnetic resonance recording is composed of a large number of individual partial scans in which raw data is recorded from different slices of the examination object, in order, subsequently, to reconstruct volume image data therefrom.

Furthermore, however, in many investigations, it is also necessary to carry out a plurality, i.e., a whole series, of magnetic resonance recordings of the examination object, wherein a particular scan parameter is varied. Based upon the scans, the effect of this scan parameter on the examination object is observed in order later to draw diagnostic conclusions therefrom. A series should be understood as being at least two, but usually more than two, magnetic resonance recordings. Usefully, therein, a scan parameter is varied such that the contrast of a particular material type excited during the scans, for example, a tissue type of the examination object or a chemical substance which is significant for most, or for particular, tissue types, for example, water, is influenced as strongly as possible by the variation of the scan parameter. This ensures that the effect of the scan parameter on the examination object is particularly visible.

A typical example for series of magnetic resonance recordings with the variation of a scan parameter strongly influencing the contrast is so-called diffusion weighting imaging (DWI) methods. Diffusion should be understood to be the Brownian motion of molecules in a medium. During diffusion-weighted imaging, typically, a plurality of images with different diffusion directions and diffusion weightings are acquired and combined with one another. The strength of the diffusion weighting is usually defined by the so-called b-value. The diffusion images with different diffusion directions and weightings, and/or the images combined therefrom, can then be used for diagnostic purposes. Thus, with suitable combinations of the diffusion-weighted images recorded, parameter maps with particular diagnostic significance can be created, for example, maps which represent the “apparent diffusion coefficient” (ADC) or the “fractional anisotropy” (FA).

Diffusion imaging is often based upon echoplanar imaging (EPI) due to the short acquisition time of the EPI sequence per image and its robustness in relation to movement.

In diffusion-weighted imaging, additional gradients are inserted into a pulse sequence to make visible or measure the diffusion properties of the tissue. These gradients have the effect that tissue with rapid diffusion (for example, cerebrospinal fluid (CSF)) is subject to a more severe signal loss than tissue with slow diffusion (for example, the grey matter tissue of the brain). The resultant diffusion contrast is gaining ever greater significance clinically, and nowadays applications go far beyond the classic early identification of ischemic strokes.

For many years, measurements of the diffusion properties in different tissue types using magnetic resonance imaging have been an indispensable tool in clinical diagnostics. Typically, diffusion encoding methods with two or more diffusion gradients having trapezoidal gradient waveforms as described by Stejskal and Tanner in “Spin Diffusion Measurements: Spin Echoes in the Presence of a Time-Dependent Field Gradient”, J. Chem. Phys. 42: pp. 288-292 (1965) are used since they are a) efficient with respect to the exploitation of the performance limits of a gradient system being used and b) easily described both in the context of diffusion models and also for technical computations (for example, regarding stimulations or limitations of the gradient system).

However, recently in the fields of research and diagnostics, there has been increased interest in more complex gradient waveforms, in particular, for tensor-weighted diffusion scans that offer access “by design” to new contrast properties, as described, for example, in the article by Szczepankiewicz et al., “Gradient Waveform Design for Tensor-Valued Encoding in Diffusion MRI”, J. Neurosc. Methods 348: p. 109007 (2021).

However, the increasing complexity of the gradient waveforms used herein presents major challenges for the preparation, planning, and execution of such scans.

For the processing of scan protocols by a user, for example, in the context of tensor-weighted diffusion scans with complex gradient waveforms, in each case, a possible value range for each scan parameter is typically presented to the user from a group of scan parameters that are to be processed. A respective value range is set in at least one of the categories “non-settable parameter values”, “conditionally settable parameter values”, and “unconditionally settable parameter values”. The allocation to such categories can be displayed in a suitable form to the user during processing of a scan protocol, for example, color-coded so that suitable parameter values can be selected for the scan parameters.

Therein, the assignment to a category A (“non-settable parameter value”) can take place if a parameter value assigned in this category A of a processed scan parameter would lead to a non-executable scan protocol. Parameter values of this type can, for example, be blocked for the user so that they cannot be selected by the user for the corresponding scan parameter.

Nevertheless, parameter values assigned to the user in this category A can be displayed or otherwise brought to notice, for example, in the event that they could be settable if the scan protocol to be processed undergoes a suitable change at another site, for example, a corresponding change of at least one other scan parameter of the scan protocol that is, in particular, in a dependency relationship to the processed scan parameter. Such dependencies of different scan parameters upon one another further enhance the complexity of the processing of scan protocols.

An assignment to a category B (“conditionally settable parameter value”) can take place if a parameter value assigned in this category B of a processed scan parameter requires an automated, in particular, clearly defined, change to a respective parameter value of at least one scan parameter different from the processed scan parameter in order to make the scan protocol capable of being carried out. The required automated change can then take place, for example, as soon as the user sets a parameter value assigned to the category B for a processed scan parameter so that the adaptations needed for an executability of the scan protocol are carried out automatically.

An assignment to a category C (“unconditional”) can then take place if a parameter value assigned in this category C of a processed scan parameter has no influence on an executability of the processed scan protocol. A parameter value of a processed scan parameter assigned to this category C can be selected without the necessity for further adaptation.

In order to make such an assignment by a user to at least one of the categories A, B, or C already while a processing of a scan protocol is underway, complex computations are necessary. In particular, since after each change of a parameter value of a scan parameter for at least one other scan parameter, but also for a plurality of other scan parameters, the respective assignments of possible parameter values to one of the categories A (“non-settable”), B (“conditionally settable”) and C (“unconditionally settable”) can change.

The computations therein comprise checking an executability of a scan protocol provided for a scan. In order to be able to use a desired non-trapezoidal gradient waveform, certain hurdles arising from the more complex variations of the gradient amplitudes must already be overcome at the stage of its description, so that it can later actually be used in practice with the desired gradient waveform. An implementation of described non-trapezoidal gradient waveforms that have been read in is also not without difficulty. The complex waveforms also present new challenges for an error-free, correct realization of the intended moments of the desired gradient waveform, in particular, even the zeroth moment, and for the compensation of accompanying Maxwell field terms and/or the avoidance of signal interferences.

So far, only prototype implementations thereof are known. With these, a user can usually select from a number of specified non-trapezoidal gradient waveforms and modify them to a certain extent. In the selection of a gradient waveform, however, dependencies with other protocol parameters are not automatically taken into account in the known method.

Some non-trapezoidal (but relatively complex) gradient waveforms can be approximated for computations needed for this purpose by way of a certain number of trapezoidal gradient waveforms. This applies, for example, for sine or cosine-type gradient waveforms. Therein, the computations needed can be carried out sufficiently rapidly provided that the number of half-waves of the gradient waveforms to be approximated is sufficiently small (for example, less than 100 half-waves). However, for more complex gradient waveforms that can be characterized by way of several hundred or thousand half-waves, this approach is no longer practicable.

In principle, a downstream (for example one-off) checking of executability of a processed scan protocol immediately before the start of the scan is also conceivable. Here, however, a user is often forced to modify their scan planning at very short notice (and possibly with a necessity for significant changes of parameter values of scan parameters). In a clinical environment, this is barely practicable.

It is a further possibility that even before a possible scan, for example, once on installation of a magnetic resonance system, scan protocols (with predetermined scan parameters) that have been tested for executability are provided. However, in clinical use, the necessary flexibility in the configuring of the scan protocols (for example, with regard to a spatial resolution, a number of slices, or parameters determining the contrast, such as an echo time TE or a repetition time TR) of individual scans that are to be executed is lacking herein.

A further possibility that could be mentioned is the use of computers with such great computing power that they could indeed carry out the necessary computations described with sufficient speed during a planning of a scan. Disadvantages of such a solution are both a high energy expenditure during operation and the costs that are associated with such high-performance computers.

### SUMMARY

It is an object of the method described to enable the user an easier, possibly interactive, planning of scans with non-trapezoidal gradient waveforms for diffusion encoding, while taking account of hardware limitations.

The object is achieved with a method for capturing diffusion-weighted scan data of an examination object with a magnetic resonance system, making use of a scan protocol with non-trapezoidal gradient waveforms for the diffusion encoding as claimed in claim 1, a magnetic resonance system as claimed in claim 9, a computer program as claimed in claim 10 and an electronically readable data carrier as claimed in claim 11.

A method according to the disclosure for capturing diffusion-weighted scan data of an examination object with a magnetic resonance system, making use of a scan protocol with non-trapezoidal gradient waveforms for the diffusion encoding, comprises the steps
a) loading a scan protocol to be used with scan parameters that are to be set and which comprise a desired non-trapezoidal gradient waveform,
b) loading prepared characteristics for at least the non-trapezoidal gradient waveform,
c) assigning possible parameter values of at least one scan parameter of the scan protocol that is to be set to at least one category, giving an executability of the scan protocol on the magnetic resonance system on the basis of the loaded characteristics,
d) inputting at least one desired parameter value of at least one scan parameter of the scan protocol, taking into account the assignment made,
e) if a parameter value has not yet been input for each scan parameter that is to be set of the scan protocol with which the scan protocol is able to be carried out, repetition of steps c) and
d), at least for scan parameters for which no parameter value has yet been set, until, for all the scan parameters of the scan protocol that are to be set, parameter values with which the scan protocol is able to be carried out are input,
g) capturing diffusion-weighted scan data using the scan protocol with the input parameter values.

The loading according to the disclosure of prepared characteristics for at least one non-trapezoidal gradient waveform of the scan protocol permits a rapid assignment of possible parameter values to one category specifying an executability of the scan protocol on the magnetic resonance system while maintaining the loaded limit values. By way of the assignment to the at least one category, it is made easier for a user, during the planning of a scan to be carried out, to find parameter values for scan parameters to be set of a scan protocol that is to be used.

A magnetic resonance system according to the disclosure comprises a magnet unit, a gradient unit, a high frequency unit, and a control facility with a monitoring unit configured for carrying out a method according to the disclosure.

A computer program according to the disclosure implements a method according to the disclosure on a control facility when it is executed on the control facility. For example, the computer program comprises commands which, when the program is executed by a control facility, for example, a control facility of a magnetic resonance system, cause said control facility to carry out a method according to the disclosure. The control facility can be constructed in the form of a computer.

Herein, the computer program can also be available in the form of a computer program product which can be loaded directly into a memory store of a control facility, having program code means in order to carry out a method according to the disclosure when the computer program product is executed in a computing unit of the control facility.

A computer-readable storage medium according to the disclosure comprises commands which, when executed by a control facility, for example, a control facility of a magnetic resonance system, cause it to carry out a method according to the disclosure.

The computer-readable storage medium can be configured as an electronically readable data carrier that comprises electronically readable control information stored thereon, which comprises at least one computer program according to the disclosure and is configured such that, when the data carrier is used in a control facility of a magnetic resonance system, it carries out a method according to the disclosure.

The advantages and embodiments set out in relation to the method apply accordingly also to the magnetic resonance system, the computer program product, and the electronically readable data carrier.

### BRIEF DESCRIPTION OF THE DRAWINGS

Further advantages and details of the present disclosure are disclosed in the exemplary embodiments described below, making reference to the drawings. The examples given do not represent any restriction of the disclosure. In the drawings:

FIG. 1 shows a schematic flow diagram of a method according to the disclosure for capturing diffusion-weighted scan data from an examination object with a magnetic resonance system, making use of a scan protocol with non-trapezoidal gradient waveforms for the diffusion encoding,

FIG. 2 shows a schematic comparison of different possible excitation types and recording types of echo signals with diffusion gradients for diffusion weighting,

FIG. 3 shows a schematically represented magnetic resonance system according to the disclosure.

### DETAILED DESCRIPTION

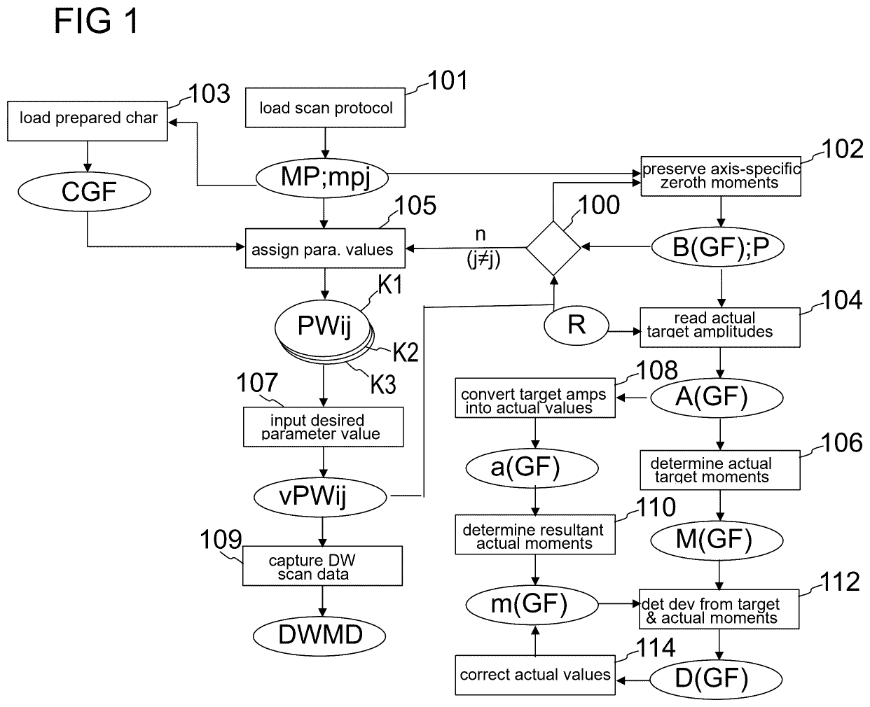

FIG. 1 is a schematic flow diagram of a method according to the disclosure for capturing diffusion-weighted scan data from an examination object with a magnetic resonance system, making use of a scan protocol with non-trapezoidal gradient waveforms for the diffusion encoding.

A scan protocol MP that is to be used is loaded (block 101) with scan parameters mpj that are to be set and that comprise a desired non-trapezoidal gradient waveform GF.

Prepared characteristics CGF for at least the desired non-trapezoidal gradient waveforms GF are loaded (block 103).

Possible parameter values PWij of at least one scan parameter mpj that is to be set for the scan protocol MP are assigned (block 105), on the basis of the loaded characteristics, to at least one category giving an executability of the scan protocol MP on the magnetic resonance system 1.

Taking account of the assignment made of the possible parameter values PWij of the scan parameters mpj of the scan protocol MP, at least one desired parameter value vPWij is input (block 107). This can take place by way of a user or automatically. By taking account of the assignment made of the possible parameter values PWij of the scan parameters mpj of the scan protocol MP to at least one category K1, K2, K3 giving an executability of the scan protocol MP on the magnetic resonance system 1, it can be ensured that the input parameter values vPWij of the scan parameters mpj of the scan protocol are able to be executed on the magnetic resonance system 1.

With a query 100, it can be determined whether a parameter value vPWij has already been set for each scan parameter mpj to be set in the scan protocol MP, with which the scan protocol can be carried out. If this is not the case (query 100, n) at least for scan parameters mpj for which so far no parameter value vPWij has been set (j≠j), possible parameter values PWij of at least one scan parameter mpj that is to be set of the scan protocol MP are assigned (block 105) anew to the at least one category K1, K2, K3 giving an executability of the scan protocol MP on the magnetic resonance system 1 on the basis of the loaded characteristics CGF. Therein, input parameter values vPWij can be taken into account, so that the assignment can possibly change. Taking account of the (renewed) assignment made of the possible parameter values PWij of the scan parameters mpj of the scan protocol MP, at least one desired parameter value vPWij is input (block 107) until parameter values vPWij have been input for all the scan parameters mpj that are to be set of the scan protocol MP, with which the scan protocol MP can be carried out. Characteristics CGF can comprise different terms and values that are of relevance for the gradient waveform GF and which, for example, can be determined in advance in pre-calculations and can be used in the planning and/or execution of a scan, which can significantly reduce the computation effort. Examples of such terms and values are described below.

Using the scan protocol MP with the input parameter values vPWij, diffusion-weighted scan data DWMD is captured and possibly further processed (block 109).

The diffusion-weighted scan data DWMD to be captured is herein, in particular, non-linear diffusion-weighted scan data DWMD, for example, trace-weighted and/or spherically diffusion-weighted scan data DWMD.

The at least one non-trapezoidal gradient waveform GF can be defined along at least one axis which extends in one direction of a coordinate system, for example, a logical coordinate system of the gradient directions Gx, Gy, Gz and wherein the at least one non-trapezoidal gradient waveform GF is possibly defined with a predetermined scaling factor assigned to the direction of the logical coordinate system.

As stated below, scan parameters mpj that are to be set for the scan protocol MP can comprise spoiler gradients, compensation gradients, and/or corrected gradient amplitudes.

A desired non-trapezoidal gradient waveform GF can herein be selected from a selection of non-trapezoidal gradient waveforms and loaded as a description of the respective non-trapezoidal gradient waveform that is disassembled into at least one section that is stored in each case in a file, individually or together for a gradient waveform. The advantages of a disassembly of this type into sections are described further below.

A zeroth moment of a desired non-trapezoidal gradient waveform GF can be checked before and/or during a capturing of diffusion-weighted scan data and, if the checking reveals a deviation from a target value, a gradient amplitude of the non-trapezoidal gradient waveform can be corrected to compensate for the deviation.

In order to be able to use non-trapezoidal gradient waveforms (also referred to as waveforms below, for short), dependent upon a scan protocol that is used, it can be useful to permit a user to specify waveforms with one or more sections DW1, DW2, DW3. For example, independently of the actual readout module, the diffusion encoding can be interrupted by one or more RF pulses. For example, a spin-echo encoding (SE) can be interrupted by one, and a double-refocused spin-echo encoding (DSE) by two, RF refocusing pulses RF2. A stimulated echo encoding (STE) can be interrupted by a “storage” RF pulse RF3 and a “recovery” RF pulse RF4. More extensive and combined encodings with (multiple) spin-echoes and (multiple) stimulated echoes are possible.

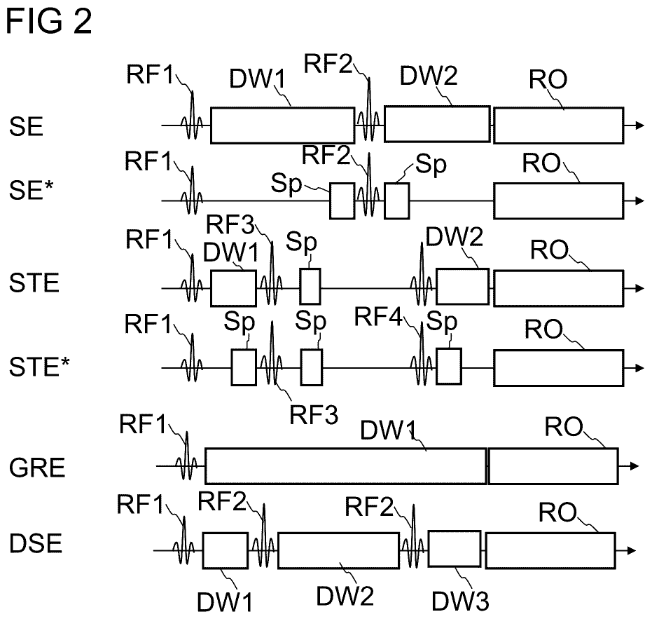

In FIG. 2, different possible scenarios are outlined wherein, in each case, the signals generated are recorded with a readout module RO after an RF excitation pulse RF1. Various known recording techniques are possible as the readout module RO. For example, a single-shot (ss)-EPI, a multi-shot (ms)-EPI, an ss-spiral, an ms-spiral, a HASTE, a turbo-spin-echo (TSE), a turbo-gradient-spin-echo (TGSE), a single spin-echo (SE), or a single gradient echo (GRE) recording technique is possible herein.

For simplification, in the representation of FIG. 2, additional imaging gradients are left out. In an STE variant, gradient pulses between a storage RF pulse RF3 and a recovery RF pulse RF4 have no effect on the diffusion encoding.

Dependent upon the encoding scheme, for example, the following assignments regarding the number of sections can be supported:

One section:

| | |
|---|---|
| GRE-encoding | |
| SE-encoding | (section #2 omitted) |
| DSE-encoding | (sections #1 and #3 omitted) |
| STE-encoding | (section #2 omitted) |

Two sections:

| | |
|---|---|
| SE-encoding | |
| DSE-encoding | (section #3 omitted) |
| STE-encoding | |

Three sections:

DSE-encoding

The definition of the individual sections can take place, as previously known, in the form of a text description. The advantage of such a description is the intuitive understanding of the content and the simple creation and amendment by the user. Ideally, a standardized format (for example, XML) is used for this. In principle, however, binary formats are also conceivable that are generated, for example, with a corresponding generating or converting program.

It can be imagined that each section is stored individually: in this case, for example, for a DSE-encoding, three separate descriptions would be available for each section DW1, DW2, DW3. However, the sections can also be available in a common description, which permits a corresponding assignment.

The description of the sections can be available fixedly encoded in the program code. Preferably, it is possible for a user to read in waveforms from an external description. For this purpose, one or more descriptions of mutually associated sections in the form of files can be provided.

It can herein be provided that the description of a waveform contains a defined spacing P respectively between two sections DW1, DW2, DW3. This is important, in particular, if an accumulated 0th gradient moment of preceding sections is different from zero. In this case, a spacing P between two sections DW1, DW2, DW3 has an influence on the shape of the diffusion encoding, so that by specifying the spacing P, this can be influenced.

The actual description of the waveform can take place as piecewise-constant. Therein, time points for the start and the end of a section are specified, and also the constant amplitude of the three gradient axes in this section. The time points can be specified in a fixed grid. The grid can be specified by the scanning system, for example, by a gradient control unit 5′.

Alternatively, as is already known, a piecewise-linear description of the waveform can be provided. Therein, time points for the start and the end of a linear section are specified, and also the respective amplitudes.

The amplitudes G(t) of the waveform can be specified in both cases in absolute values (typically in units of mT/m); however, the diffusion weighting (b-value) is thereby fixedly specified. Preferably, the amplitudes are defined with relative, for example, normalized, values (for example, in an interval from −1 to +1), so that an actual scaling to the required absolute amplitudes can take place later on the basis of the requested b-value.

The amplitudes G(t) can relate, as already known, to “physical” or “logical” coordinates. “Physical” coordinates relate here to the three axes of the gradient coil (x, y, z) and have the advantage that, independently of the orientation of the recording, the maximum efficiency (in particular, the maximum amplitude) can be used on each gradient axis. “Logical” coordinates relate here to the three axes of the image encoding (readout encoding, phase encoding, slice encoding) and have the advantage that, independently of the orientation of the recording, an unambiguous relationship of the diffusion encoding relative to the recorded slice is ensured.

The description can contain a comment field, which is displayed as an indication to the user in the later scan planning.

Some examples of possible descriptions of non-trapezoidal waveforms now follow:

### Example 1: Common Description for Two Sections in XML Format as Piecewise-Linear

```
<!-- Description of the shape -->
<Value Name=“Comment” Data=“Basic Triple Diffusion Encoding” Type=“String”/>
<!-- Shape format (linear / steps) -->
<Value Name=“Format” Data=“linear” Type=“String”/>
<Folder Name=“Sections”>
  <Folder Name=“0”>
    <!-- Before refocusing: |+X|Pause|−X|+Z| -->
    <!-- Time[us] x y z -->
    <Value Name=“Vector(0)” Data=“ 0, 0.0000, 0.0000, 0.0000” Type=“String”/>
    <Value Name=“Vector(1)” Data=“ 1000, 1.0000, 0.0000, 0.0000” Type=“String”/>
    <Value Name=“Vector(2)” Data=“ 10000, 1.0000, 0.0000, 0.0000” Type=“String”/>
    <Value Name=“Vector(3)” Data=“ 11000, 0.0000, 0.0000, 0.0000” Type=“String”/>
    <Value Name=“Vector(4)” Data=“ 18000, 0.0000, 0.0000, 0.0000” Type=“String”/>
    <Value Name=“Vector(5)” Data=“ 19000, −1.0000, 0.0000, 0.0000” Type=“String”/>
    <Value Name=“Vector(6)” Data=“ 28000, −1.0000, 0.0000, 0.0000” Type=“String”/>
    <Value Name=“Vector(7)” Data=“ 29000, 0.0000, 0.0000, 0.0000” Type=“String”/>
    <Value Name=“Vector(8)” Data=“ 30000, 0.0000, 0.0000, 1.0000” Type=“String”/>
    <Value Name=“Vector(9)” Data=“ 39000, 0.0000, 0.0000, 1.0000” Type=“String”/>
    <Value Name=“Vector(10)” Data=“ 40000, 0.0000, 0.0000, 0.0000” Type=“String”/>
    <!-- Optional: Gap duration after the section [us] -->
    <Value Name=“Gap” Data=“ 7000” Type=“String”/>
  </Folder>
  <Folder Name=“1”>
    <!-- After refocusing: |+Z|−Y|Pause|+Y|-->
    <!-- Time[us] x y z -->
    <Value Name=“Vector(0)” Data=“ 0, 0.0000, 0.0000, 0.0000” Type=“String”/>
    <Value Name=“Vector(1)” Data=“ 1000, 0.0000, 0.0000, 1.0000” Type=“String”/>
    <Value Name=“Vector(2)” Data=“ 10000, 0.0000, 0.0000, 1.0000” Type=“String”/>
    <Value Name=“Vector(3)” Data=“ 11000, 0.0000, 0.0000, 0.0000” Type=“String”/>
    <Value Name=“Vector(4)” Data=“ 12000, 0.0000, −1.0000, 0.0000” Type=“String”/>
    <Value Name=“Vector(5)” Data=“ 21000, 0.0000, −1.0000, 0.0000” Type=“String”/>
    <Value Name=“Vector(6)” Data=“ 22000, 0.0000, 0.0000, 0.0000” Type=“String”/>
    <Value Name=“Vector(7)” Data=“ 29000, 0.0000, 0.0000, 0.0000” Type=“String”/>
    <Value Name=“Vector(8)” Data=“ 30000, 0.0000, 1.0000, 0.0000” Type=“String”/>
    <Value Name=“Vector(9)” Data=“ 39000, 0.0000, 1.0000, 0.0000” Type=“String”/>
    <Value Name=“Vector(10)” Data=“ 40000, 0.0000, 0.0000, 0.0000” Type=“String”/>
  </Folder>
</Folder>
```

### Example 2: Description of a Section in XML Format as Piecewise-Constant

```
  <!-- Description of the shape -->
  <Value Name = “Comment” Data = “Basic diagonal ‘sine’ shape” Type = “String”/>
  <!-- Shape format (linear / steps) -->
  <Value Name = “Format” Data = “steps” Type = “String”/>
  <Folder Name = “Sections”>
    <Folder Name = “0”>
      <!-- Before refocusing: |+X/+Y/+Z|−X/−Y/−Z| -->
      <!-- Time[us] x y z -->
      <Value Name = “Vector(0)” Data = “ 0,0.00157,0.00157,0.00157” Type = “String”/>
      <Value Name = “Vector(1)” Data = “ 10,0.00314,0.00314,0.00314” Type = “String”/>
      <Value Name = “Vector(2)” Data = “ 20,0.00471,0.00471,0.00471” Type = “String”/>
      <Value Name = “Vector(3)” Data = “ 30,0.00628,0.00628,0.00628” Type = “String”/>
      <Value Name = “Vector(4)” Data = “ 40,0.00785,0.00785,0.00785” Type = “String”/>
      <Value Name = “Vector(5)” Data = “ 50,0.00942,0.00942,0.00942” Type = “String”/>
      <Value Name = “Vector(6)” Data = “ 60,0.01099,0.01099,0.01099” Type = “String”/>
      <Value Name = “Vector(7)” Data = “ 70,0.01256,0.01256,0.01256” Type = “String”/>
        ...
      <Value Name = “Vector(3999)” Data = “39990,0.00000,0.00000,0.00000” Type =
“String”/>
    </Folder>
  </Folder>
```

At the start of a scan planning, a totality of descriptions of available waveforms can be read in. As mentioned, these can be stored fixedly encoded into the program or in particular files (or in a particular directory). During the scan planning, the different waveforms can then be offered to a user in a “Selection Menu” for selection.

Preferably, during the scan planning, the user is given the possibility, via standard methods (for example, an “Open file” dialogue), of importing the desired waveform(s) from a description file. Advantageously, already at this time point, for example, at the query (100), a validity of the waveform description is checked (and possibly errors in the format are indicated), a compatibility of the waveform with the current scan protocol MP is checked, if necessary or useful, dependent scan parameters are adapted and/or pre-calculations are carried out for a rapid scan planning and execution.

During a procedure of a reading-in of a waveform from a description, it should be noted that the accuracy of the settability of desired amplitudes can be restricted. For example, a DAC converter of a magnetic resonance system can represent only a limited number of values. It is also conceivable that, for technical reasons (for example, limited scope of data packets and runtime performance), a data transport layer in the scanning system supports a lower accuracy in the mapping of amplitude values. If the amplitude values of the waveforms are now defined with high accuracy (for example, with double floating point precision), but applied with reduced accuracy (for example, single floating point or fixed point precision), the resulting 0th gradient moment M_{x/y/z}=G∫dt f_{x/y/z}(t) can deviate from the target value, which leads directly to a signal loss.

Conventionally, such deviations have been calculated and compensated for, as far as possible, via a separate so-called “balance” gradient. A disadvantage herein is that this additional “balance” gradient needs time and that the actual diffusion encoding herein deviates from that desired.

In an exemplary embodiment, in order to ensure a preservation of the axis-specific zeroth moments after receipt (block 102) of a description B (GF) of a non-trapezoidal waveform, it is possible to proceed according to the following fundamental concept:
1. Read in (block 104) actual target amplitudes A (GF) with high precision.
2. Determine (block 106) therefrom for each axis, actual target moments M(GF) with high precision.
3. Convert (block 108) target amplitudes A (GF) into displayable actual values a (GF) with low precision.
4. Determine (block 110) therefrom resultant actual moments m(GF) with high precision.
5. Determine (block 112) the deviation D(GF) from target moments M(GF) and actual moments m(GF) with high precision.
6. Take into account (block 114) the accumulated deviation D(GF) and possibly correct actual values m(GF), a (GF) such that the actual moments m(GF) correspond to the target moments M(GF) as well as possible.

On reading-in of the waveform, at the same time, it can be taken into account that some scanning systems require, for the execution, a description of the gradient pulse on a defined time grid. For example, it can be necessary to convert the waveform to a fixed grid of 1 μs, 10 μs or 50 μs. According to the disclosure, in this conversion—which can possibly occur in one step with the reading-in of the piecewise-linear or piecewise-constant description—axis-specific 0th moments are also preserved with high precision.

In practice, this can have the result, for example, that in one portion with a constant target amplitude, the actual amplitude fluctuates temporally (a behavior also called “jitter”). In this way, in the temporal integral, the target moment is realized with a high degree of precision.

The following pseudo-code demonstrates in an exemplary manner, for one of the three axes, a reading-in and a gridding R used for piecewise-constant sections:
T[i] are the support points (i.e. the start and end points of an interval; in this example, T[i]=kᵢ*T_{Raster} where kᵢ∈N₀), G[i] are the target amplitudes with high precision, g[i] are the actual values with low precision, T_{Raster} is the time grid specified by the scanning system. The first For-loop extends over the piecewise-constant portions of the description and the second For-loop extends within the just processed portion over the grid points:

```
- M_{residual} = 0
- For (i = 0 ... N − 1)
  ∘ Nₛₜₐᵣₜ = T[i]/Tᵣₐₛₜₑᵣ, N_{end} = T[i+1]/Tᵣₐₛₜₑᵣ
  ∘ M_{desired} = G[i] * (N_{end} − Nₛₜₐᵣₜ) * Tᵣₐₛₜₑᵣ + M_{residual}
  ∘ M_{accumulated} = 0
  ∘ For (n = Nₛₜₐᵣₜ ... N_{end} − 1)
    □ M_{remaining} = M_{desired} − M_{accumulated}
    □ N_{remaining} = (N_{end} − n)
    □ T_{remaining} = N_{remaining} * Tᵣₐₛₜₑᵣ
    □ G_{current} = M_{remaining}/T_{remaining}
    □ g[i] = Round(G_{current}) // convert to reduced precision
    □ M_{accumulated} = M_{accumulated} + g[i] * Tᵣₐₛₜₑᵣ
  ∘ M_{remaining} = M_{desired} − M_{accumulated}
```

Provided the piecewise-constant description is present throughout on the fixed hardware grid R (for example, with a grid time of 10 μs as in the XML example above), the pseudo-code is simplified (again, by way of example, for one of the three axes), as follows:

```
- M_{residual} = 0
- For (i = 0 ... N − 1)
  ∘ M_{desired} = G[i] * Tᵣₐₛₜₑᵣ + M_{residual}
  ∘ G_{current} = M_{desired}/ Tᵣₐₛₜₑᵣ
  ∘ g[i] = Round(G_{current}) // convert to reduced precision
  ∘ M_{residual} = M_{desired} − g[i] * Tᵣₐₛₜₑᵣ
```

Such an algorithm can be used not only, as described above, for a moment-preserving reading-in of non-trapezoidal waveforms in the scan preparation, but can also be used for a preservation of the 0th moments of the waveforms, for example, after applying corrections and transformations, in the performance of the scan.

Piecewise-linear sections (G[i] are the support target values with high precision, g[i] are the actual values with low precision; the specified grid for g[i]) can be converted as follows (again, by way of example, for one of the three axes):

```
- M_{residual} = 0, i = 0
- While (i < N)
  ∘ Nₛₜₐᵣₜ = T[i]/Tᵣₐₛₜₑᵣ, N_{end} = T[i+1]/Tᵣₐₛₜₑᵣ
  ∘ G_{average} = (G_{desired}[i] + G_{desired}[i+1])/2
  ∘ M_{desired} = G_{average} * (N_{end} − Nₛₜₐᵣₜ) * Tᵣₐₛₜₑᵣ + M_{residual}
  ∘ M_{accumulated} = 0
  ∘ For (n = Nₛₜₐᵣₜ ... N_{end})
    □ M_{remaining} = M_{desired} − M_{accumulated}
    □ N_{remaining} = (N_{end} − n)
    □ T_{remaining} = N_{remaining} * Tᵣₐₛₜₑᵣ
    □ G_{actual}[i] = (M_{remaining}/T_{remaining}) * (2 − 1/ N_{remaining})
        − G_{desired}[i+1] * (1 − 1/ N_{remaining})
    □ g[i] = Round(G_{actual}[i]) // convert to reduced precision
    □ M_{accumulated} = M_{accumulated} + g[1] * Tᵣₐₛₜₑᵣ
  ∘ M_{residual} = M_{desired} − M_{accumulated}
```

For checking purposes, it can be provided that the user can export the converted grid data in a suitable form (for example, as an XML file in grid format).

Furthermore, it can be provided to check the read-in waveforms, for example, by means of the query 100, regarding their validity. Apart from purely semantic checking (text and number formatting) and a check of the validity of parameter ranges (amplitude and time data), in particular, the usability of at least one of the encodings (GRE, SE, DSE, STE) can be checked. A use is possible if the time integral of the 0th gradient moment on each axis, taking account of the respective signal path, almost disappears:

| - GRE: ∫dt f_{#1}(t) = 0 | |
|---|---|
| - SE, STE: | ∫dt f_{#1}(t) − ∫dt f_{#2}(t) = 0 |
| - DSE: | ∫dt f_{#1}(t) − ∫dt f_{#2}(t) + ∫dt f_{#3}(t) = 0 |

In order to link a scan protocol MP unambiguously to a waveform description, a checksum can be calculated and stored with the scan protocol. In this way, the validity of a created scan protocol can be ensured: if after reading-in of the waveform, the associated description is changed (for example, by changing the associated text file), this deviation is recognized by way of comparison of the checksums: the execution of the now inconsistently parameterized scan can thus be refused. In principle, it would be possible to achieve a consistency check by storing the complete waveform in the scan protocol; however, for extensive waveforms, the datasets needed for them become huge.

The checksum can take account, for example, of the number of sections, the time and amplitude data for the three axes, and the possibly provided pauses between the sections. For example, a standardized checksum calculation can take place (for example, according to CRC-32).

Dependent upon a read-in waveform GF, it can be useful or necessary to set further scan parameters mpj or to change them such that an execution of the scan becomes possible and/or the image quality is improved. The selection of this waveform GF would then be a “conditionally settable parameter value”.

After reading-in of a waveform GF, a suitable encoding scheme can be set, for example, automatically. Herein, “suitable” means a) the number of sections is compatible with the scheme and b) the time integral of the 0th moment is compatible with the scheme. For example, for a description of a waveform with two sections DW1, DW2 and ∫dt f_{#1}(t)−∫dt f_{#2}(t)=0, a spin-echo (SE) encoding can be activated automatically.

Following a reading-in of a waveform GF, additionally or alternatively, a suitable direction assignment for a diffusion direction that is to be achieved can be set automatically. For example, the direction assignment with which the waveform is applied in its native form G′(t)=R G(t) with the rotation matrix R=1 can be set.

Following reading-in of a waveform GF with specified spacing P between two sections DW1, DW2, DW3, it can be checked whether this spacing can actually be realized. If not, a mode can be activated automatically in which the spacings P of the sections DW1, DW2, DW3 can be freely set by a user in divergence from the originally specified value. The spacings P can be determined, for example, automatically, such that they are compatible with the current scan protocol MP.

For example, with a spin-echo (SE) encoding, the spacing P between section DW1 and section DW2 can be limited by the duration P of the refocusing module in which the RF refocusing pulse RF2 is radiated in.

Following the reading-in of a waveform GF, it can be further checked whether the 0th moment (implicit spoil moment) realized by the diffusion gradients of individual sections DW1, DW2, DW3 lies, for all the b-values≠0 set in the protocol, above a threshold value. If this is not the case, additional spoiler gradients can be automatically activated in the scan protocol in order to reduce signal contributions of undesirable signal paths (for example, signal paths of a free induction decay (FID)). A determination of such spoiler gradients is described, for example, in U.S. Pat. No. 10,557,909B2.

In FIG. 2, for an SE-encoding SE* without diffusion encoding, i.e., for b=0, spoiler gradients Sp that can be switched before and after the RF refocusing pulse RF2 are shown. Similarly, for an STE-encoding STE* without diffusion encoding, i.e., for b=0, spoiler gradients Sp are shown.

Alternatively, from the scan protocol MP, the b-values≠0 for which the 0th moment realized by the diffusion gradients lies below the threshold value are discarded. If, for example, scans with b=0, 200, 400, 700, 1000 s/mm² are intended and the threshold value is first reached at b=500 s/mm², the number of the b-value can be automatically reduced by 3 so that only b=0, 700, 1000 s/mm² remain preserved.

The threshold value can therein be specified, for example, as a multiple of a spoil moment M_{SP} which leads, within a voxel, to a dephasing of the magnetization of 2π.

The determination and use of spoil moments can be utilized not only for determining and describing parameter dependencies in the scan planning, but also for a targeted (de) activation of spoiler gradients during the scan execution.

Ideally, the user of the system is automatically informed about the changes undertaken.

During a subsequent scan planning (that is, the processing of the scan protocol for the discovery of usable parameter values), the dependencies can also be further checked and taken into account. Therein, “non-settable parameter values”, “conditionally settable parameter values”, and “unconditionally settable parameter values” can be displayed to the user in a suitable form (for example, color-coded or with some other identification).

For example, a user can also switch over during a scan planning between an SE-encoding and an STE-encoding. The necessary requirements placed on the waveform GF are identical (one or two sections, ∫dt f_{#1}(t)−∫dt f_{#2}(t)=0). As a further example, the user can switch between “flexible” and “specified” spacings P between the sections DW1, DW2, DW3 provided it permits the current scan protocol MP (for example after the user has selected a shorter refocusing module). Furthermore, the user could deactivate additional spoil gradients as soon as the b-values set in the scan protocol no longer unconditionally require them.

In addition, it can be provided to the user during the scan planning to provide information regarding actual time intervals—for example, in the form of a notification text. In this way, the user is made able to optimize waveforms for a particular scan protocol. The time intervals can comprise, for example, a maximum available duration for each section DW1, DW2, DW3, an actual duration of each section DW1, DW2, DW3, a minimum necessary duration of the spacing P between two sections DW1, DW2, DW3 and/or an actual duration of the spacing P between two sections DW1, DW2, DW3.

In general, it can further be provided that in a scan, different gradient waveforms GF are used one after the other (or nested). This is relevant, for example, if differences in the diffusion contrast dependent upon the waveform are to be established and represented. For example, initially, a first waveform with a plurality of diffusion weightings (b-values) can be measured, and therefrom, a first ADC can be determined, and thereafter, this is repeated within the scan for a second waveform. From the data, an absolute (aADC=(ADC₂−ADC₁)) or relative (rADC=(ADC₂−ADC₁)/ADC₁) deviation can thus be determined and represented as a map. A method of this type is disclosed, for example, in U.S. Pat. No. 10,006,979B2. What is advantageous in the recording of both waveforms in a scan is the high level of consistency of the data (for example, with regard to the movement of the patient or to the adjustment data or calibration data).

Further gradient waveforms GF can be stored with their sections DW1, DW2, DW3 in separate files or—preferably—in a file with a correspondingly extended format. For example, (both for piecewise-constant and also in a piecewise-linear definition) the data rows can be correspondingly expanded, for example, in the following form:

<!-- Time[us] x1 y1 z1 x2 y2 z2 -->
<Value Name=“Vector(0)” Data=“0,+0.01,+0.02,−0.02,+0.03,−0.01,−0.01” Type=“String”/>

It can be provided that in a scan, different rotations and/or scalings of the gradient waveform are used one after the other (or nested). This is relevant, for example, if a diffusion tensor is to be established from the scan and represented.

A scaling of the waveform GF with which a changed b-value for this execution is associated is, for example, possible with a scaling matrix S=((S, 0, 0), (0, S, 0), (0, 0, S)), so that the following applies:

$${f}^{′} ( t ) = \underline{S} f ( t ) \qquad f ( t ) = ( {f}_{x} ( t ) , {f}_{y} ( t ) , {f}_{z} ( t ) )$$

A rotation of the waveform GF with which a changed rotation of the b-matrix for this embodiment is associated is possible with a rotation matrix R, so that the following applies:

$$\begin{matrix}{f}^{′} ( t ) = \underline{R} f ( t ) & f ( t ) = ( {f}_{x} ( t ) , {f}_{y} ( t ) , {f}_{z} ( t ) )\end{matrix} .$$

A rotation in three-dimensional space can be defined unambiguously with three values—for example, the Euler angles. How a rotation matrix can be created therefrom is known to a person skilled in the art. Scaling and rotation can both be specified via a transformation matrix T=RS=S R.

For example, the elements of all the transformation matrices to be used during the scan can be specified by the user. Also conceivable here are fixed encodings (for example, with selection by the user) or a specification and reading-in via a suitable file format, for example, XML.

The specification can be restricted to the minimum necessary number of parameters, that is, for example, three Euler angles (and possibly a scaling parameter). Alternatively, the specification can contain all nine (partially redundant) elements of the transformation matrix: this has the advantage of an intuitive capturing of the rotation. From the specified direction vectors of the rotated axes in the original coordinate system (x′=(xₓ, x_{y}, x_{z}), y′=(yₓ, y_{y}, y_{z}), z′=(zₓ, z_{y}, z_{z})) and the additional scaling S, there results the transformation matrix T=S ((xₓ, yₓ, zₓ), (x_{y}, y_{y}, z_{y}), (x_{z}, y_{z}, z_{z})). Therein, |x′|=|y′|=|z′|=1 (normalization of the axes) and x′ y′=x′ z′=y′ z′=0 (pairs of perpendicular axes).

Rather than a description of different non-trapezoidal waveforms on the three axes, it can be provided that the same non-trapezoidal waveforms are used G(t)=G f(t) (fₓ, f_{y}, f_{z}) and/or (preferably) a non-trapezoidal waveform on one axis, for example, on the x-axis G(t)=G (fₓ(t), 0, 0). With this approach, the complex diffusion encodings described above-such as spherical tensor encoding-cannot be realized. Nevertheless, this approach offers access to new (for example time-dependent) diffusion properties and permits, in particular, the combination of non-trapezoidal waveforms with “diffusion directions” in the conventional sense. The diffusion directions are therein described by a set of N vectors vₙ=(v_{n,x}, v_{n,y}, v_{n,z}) and the waveforms to be used one after the other in the scan result from Gₙ(t)=G f(t) vₙ. In this way, for example, conventional diffusion scans can be carried out with a determination of trace images or diffusion tensor imaging (DTI) with a determination of maps of the tensor properties (aside from the trace, for example, anisotropy measures such as the fractional anisotropy FA or the radial anisotropy RA) as known from the prior art.

The definition of a gradient waveform GF can then be restricted to the listing of the support points for one axis. The description of the waveform GF can contain an information item with which the read-in procedure recognizes a “single axis mode” and the data is processed accordingly.

As mentioned, in diffusion scans with more than one RF pulse, it should be noted that aside from a desired signal path (for example, a spin-echo, SE), a plurality of undesirable signal paths (for example, free induction decays, FID) are generated. Complex diffusion encodings with three or more RF pulses (for example, double-refocused spin-echoes (DSE)) can therefore barely be used without dedicated sequences of additional spoiler gradients, as described, for example, in U.S. Pat. No. 9,952,302B2. However, in simple diffusion encodings that are frequently used in clinical routine, undesirable signal paths can be implicitly so strongly suppressed even by the diffusion gradients that no additional spoiler gradients are needed, and the scan can thus be configured more efficient. It is only below a particular amplitude of the diffusion gradients—for example, during a scan with a b-value of 0—that the implicit suppression is insufficient. In this case, spoiler gradients Sp are switched in place of the diffusion gradients.

These simple experiments include spin-echo (SE) and stimulated echo encoding (STE) as shown in FIG. 2, in particular with the lines SE* and STE* without diffusion encoding.

In the context of an SE-encoding, the signal path of the spin-echo is desirable, but the two FID signal paths arising after the RF pulses RF1 and RF2 are not. In an STE-encoding, the stimulated echo signal is desired, but the three FID signal paths arising after the RF pulses RF1, RF3 and RF4, the three spin-echo signal paths generated by a combination, in each case, of two of the three RF pulses RF1, RF2, RF3 and the double spin-echo signal path generated by the three RF pulses RF1, RF2, RF3 are not.

As described above, as a measure for a “sufficient” suppression of undesirable signal paths, a spoil moment M above a specified limit value M_{SP} can be required. For an example with M_{SP}=a/(γP) having the gyromagnetic ratio γ, the pixel size P and a factor a, if a=2, γ=2π*42.575 MHz/T and P=1 mm, there results, for example, M_{SP}≈7.5 mT/m ms.

It is known that, for an SE experiment, the implicit suppression of undesired signal paths is sufficient if the 0th moment of the diffusion gradients in both section #1 (M_{D,1}) and also in section #2 (M_{D,2}) is above the limit value: |M_{D,1}|≥M_{SP}, |M_{D,2}|≥M_{SP}.

According to the disclosure, 0th moments of the non-trapezoidal waveforms Gᵢ(t)=G fᵢ(t) are precalculated and stored in the scan preparation: m_{D,i}=∫dt fᵢ(t). During the scan execution, for the diffusion weighting (b-value) that is currently to be measured, it can be checked, for example, by means of the query 100, whether the condition |G m_{D,i}|≥M_{SP} is met for each section DW1, DW2. If the condition is met, the intended non-trapezoidal waveform GF can be used. If the condition is not met, a pair of spoiler gradients Sp having the moment M_{SP} can be used instead.

Preferably, during the checking of the condition of the amount of the implied spoil moment on the three gradient axes, |m_{D,i}|=√(m^{T}_{D,i} m_{D,i}) is used since-depending upon the waveform in each case-one or two components of fᵢ(t)=(f_{x,i}(t), f_{y,i}(t), f_{z,i}(t)) can be zero.

With a sufficiently dense support point grid R, the integrals become simplified to summation over values that are constant during a grid interval.

It is also known that for an STE experiment, the implicit suppression of undesired signal paths is sufficient if the 0th moment of the diffusion gradients both in section #1 (M_{D,1}) also in section #2 (M_{D,2}) is above a limit value: |M_{D,1}|>2 M_{SP}, |M_{D,2}|≥2 M_{SP} and simultaneously between RF storage and RF recovery with an additional spoiler gradient, a 0th moment |M_{Z}|>M_{SP} is realized.

Herein also, in the scan preparation, 0th moments of the non-trapezoidal waveforms Gᵢ(t)=G fᵢ(t) are pre-calculated and stored: m_{D,i}=∫dt fᵢ(t). During the scan execution, for the diffusion weighting (b-value) that is currently to be measured, it can be checked whether the condition |G m_{D,i}|≥2 M_{SP} is met for each section. If this is the case, the intended non-trapezoidal waveform GF can be used. If, however, the condition is not met, a pair of spoiler gradients Sp having a moment M_{SP} can be used instead.

In addition, it can be provided that in each case, an already described additional spoiler gradient having a moment |M_{Z}|=M_{SP} is applied. As in the SE experiment, during the checking of the condition, the amount of the implicit spoil moments can be made use of.

Such pre-calculated normalized spoil moments can be included by loaded characteristics so that during a scan planning and/or execution, a determination of the implicit spoil moments can be carried out rapidly on the basis of the normalized pre-calculation.

“Maxwell terms” should be understood, in the switching of “linear” gradient fields along the main field axis B_{z}(r)=Gₓ x+G_{y} y+G_{z} z as the unavoidably occurring transverse components Bₓ(r)=Gₓ (z+z₀ₓ)−αG_{z} (x+x₀) and B_{y}(r)=G_{y}(z+z_{0y})−(1−α) G_{z} (y+y₀). They can impress an additional phase upon the signal, dependent upon the position r, and thus, for example, lead to undesirable signal loss through dephasing within a voxel. The values z₀ₓ, z_{0y}, x₀, y₀ and α depend upon the design of the gradient coils. For “symmetrical” gradient coils typically used in whole-body scanners, x₀=y₀=z₀ₓ=z_{0y}=0 und α=1/2 applies.

It is known and usual to approximate a quantity of the magnetic field that is relevant for MR physics by means of a series expansion in order, on this basis, to carry out corrections, wherein the following applies:

$$\vert B \vert \approx {B}_{0}^{0 th} + {B}_{0}^{1 st} + {B}_{0}^{2 nd}$$

with terms for 0th order (“B₀-like”), 1st order (“gradient-like”) and 2nd order:

$${B}_{0}^{0 th} = {B}_{0} + {G}_{x}^{2} {z}_{0 x}^{2} / 2 {B}_{0} + {G}_{y}^{2} {z}_{0 y}^{2} / 2 {B}_{0} + {α}^{2} {G}_{z}^{2} {x}_{0}^{2} / 2 {B}_{0} + {( 1 - α )}^{2} {G}_{z}^{2} {y}_{0}^{2} / 2 {B}_{0} - α {G}_{x} {G}_{z} {x}_{0} {z}_{0 x} / {B}_{0} - ( 1 - α ) {G}_{y} {G}_{z} {y}_{0} {z}_{0 y} / {B}_{0}$$

$${B}_{0}^{1 st} = {G}_{x} x + {G}_{y} y + {G}_{z} z + {G}_{x}^{2} z {z}_{0 x} / {B}_{0} + {G}_{y}^{2} z {z}_{0 y} / {B}_{0} + {α}^{2} {G}_{z}^{2} x {x}_{0} / {B}_{0} + {( 1 - α )}^{2} {G}_{z}^{2} y {y}_{0} / {B}_{0} - α {G}_{x} {G}_{z} ( x {z}_{0 x} + z {x}_{0} ) / {B}_{0} - ( 1 - α ) {G}_{y} {G}_{z} ( y {z}_{0 y} + z {y}_{0} ) / {B}_{0}$$

$${B}_{0}^{2 nd} = {G}_{x}^{2} {z}^{2} / 2 {B}_{0} + {G}_{y}^{2} {z}^{2} / 2 {B}_{0} + {α}^{2} {G}_{z}^{2} {x}^{2} / 2 {B}_{0} + {( 1 - α )}^{2} {G}_{z}^{2} {y}^{2} / 2 {B}_{0} - 2 α {G}_{x} {G}_{z} x z / 2 {B}_{0} - 2 ( 1 - α ) {G}_{y} {G}_{z} y z / 2 {B}_{0}$$

For the special case of a symmetrical gradient coil, this becomes simplified to:

$${B}_{0}^{0 th} = {B}_{0}$$

$${B}_{0}^{1 st} = {G}_{x} x + {G}_{y} y + {G}_{z} z$$

$${B}_{0}^{2 nd} = {G}_{x}^{2} {z}^{2} / 2 {B}_{0} + {G}_{y}^{2} {z}^{2} / 2 {B}_{0} + {G}_{z}^{2} {x}^{2} / 8 {B}_{0} + {G}_{z}^{2} {y}^{2} / 8 {B}_{0} - {G}_{x} {G}_{z} x z / 2 {B}_{0} - {G}_{y} {G}_{z} y z / 2 {B}_{0} .$$

It is known how deviations from an idealized magnetic field without Maxwell terms (|B_{idea}|=B₀+Gₓ x+G_{y} y+G_{z} z) can be compensated for. For asymmetrical gradient coils, for this purpose, for example, additional gradient fields are switched, which compensate specifically for first-order deviations:

$$Δ {G}_{x} = {α}^{2} {G}_{z}^{2} {x}_{0} / {B}_{0} - α {G}_{x} {G}_{z} {z}_{0 x} / {B}_{0}$$

$$Δ {G}_{y} = {( 1 - α )}^{2} {G}_{z}^{2} y {y}_{0} / {B}_{0} - ( 1 - α ) {G}_{y} {G}_{z} {z}_{0 y} / {B}_{0}$$

$$Δ {G}_{z} = {G}_{x}^{2} {z}_{0 x} / {B}_{0} + {G}_{y}^{2} {z}_{0 y} / {B}_{0} - α {G}_{x} {G}_{z} {x}_{0} / {B}_{0} - ( 1 - α ) {G}_{y} {G}_{z} {y}_{0} / {B}_{0}$$

Both for symmetrical and also for asymmetrical gradient coils, the second order deviations can additionally be at least partially compensated for in that they are expanded locally (for example, about the mid-point of a slice with the coordinates r_{M}=(x_{M}, y_{M}, z_{M})) as far as the first order and then again are compensated for with additional gradient fields:

$$Δ {G}_{x} ( {r}_{M} ) = {α}^{2} {G}_{z}^{2} {x}_{M} / {B}_{0} - α {G}_{x} {G}_{z} {z}_{M} / {B}_{0}$$

$$Δ {G}_{y} ( {r}_{M} ) = {( 1 - α )}^{2} {G}_{z}^{2} {y}_{M} / {B}_{0} - ( 1 - α ) {G}_{y} {G}_{z} {z}_{M} / {B}_{0}$$

$$Δ {G}_{z} ( {r}_{M} ) = {G}_{x}^{2} {z}_{M} / {B}_{0} + {G}_{y}^{2} {z}_{M} / {B}_{0} - α {G}_{x} {G}_{z} {x}_{M} / {B}_{0} - ( 1 - α ) {G}_{y} {G}_{z} {y}_{M} / {B}_{0}$$

These compensations are not restricted to trapezoidal waveforms: for non-trapezoidal waveforms, the shape of the compensation gradients G_{C} is calculated for imaging about a reference point r_{M} as G_{C}(t, r_{M})=G² f_{C}(t, r_{M})=G² (f_{C,x} (t, r_{M}), f_{C,y} (t, r_{M}), f_{C,z} (t, r_{M})) where

$${f}_{C , x} ( t , {r}_{M} ) = - ( {α}^{2} {{f}_{z} ( t )}^{2} ( {x}_{0} + {x}_{M} ) / {B}_{0} - α {f}_{x} ( t ) {f}_{z} ( t ) ( {z}_{0 x} + {z}_{M} ) / {B}_{0} )$$

$${f}_{C , y} ( t , {r}_{M} ) = - ( {( 1 - α )}^{2} {{f}_{z} ( t )}^{2} ( {y}_{0} + {y}_{M} ) / {B}_{0} - ( 1 - α ) {f}_{y} ( t ) {f}_{z} ( t ) ( {z}_{0 y} + {z}_{M} ) / {B}_{0} )$$

$${f}_{C , z} ( t , {r}_{M} ) = - ( {{f}_{x} ( t )}^{2} ( {z}_{0 x} + {z}_{M} ) / {B}_{0} + {{f}_{y} ( t )}^{2} ( {z}_{0 y} + {z}_{M} ) / {B}_{0} - α {f}_{x} ( t ) {f}_{z} ( t ) ( {x}_{0} + {x}_{M} ) / {B}_{0} - ( 1 - α ) {f}_{y} ( t ) {f}_{z} ( t ) ( {y}_{0} + {y}_{M} ) / {B}_{0} )$$

Since these progressions depend upon the location of the reference point (and possibly upon additional rotations of the waveform), pre-calculations are possible to only a limited extent. In principle, for this purpose, all the locations (and rotations) at the time point of the scan preparation must be known, and the complete range of the compensation waveforms calculated and stored. Alternatively, the compensation waveforms are calculated during the scan execution in real time.

However, an accuracy of the setting capability of desired amplitudes cannot be restricted for non-trapezoidal waveforms. For example, the DAC converter can represent only a limited number of values. It is also conceivable that, for technical reasons (for example, limited scope of data packets and runtime performance), a data transport layer in the scanning system only supports a lower accuracy in the representation of amplitude values. If the amplitude values of the compensation gradients are now defined with high accuracy (for example, with double floating point precision), but applied with reduced accuracy (for example, single floating point or fixed point precision), the resulting 0th gradient moment M_{C,x/y/z}=G ∫dt f_{C,x/y/z}(t) can deviate from the target value, which leads directly to a signal loss. A solution to this problem is described below.

Firstly, however, a new approach should be described which enables a rapid pre-calculation for carrying out additional slice-specific Maxwell corrections for non-trapezoidal waveforms in the case of a simultaneous multislice imaging (SMS).

For example, in U.S. Pat. No. 10,613,175B2, methods with SMS for slice-specific Maxwell corrections for trapezoidal waveforms are described in which the following scheme is used:
1. Determining a reference point (for example, the mid-point r_{SMS} of all the simultaneously excited slices).
2. Determining compensation gradients for this reference point (for example G_{C}(t, r_{SMS})=G² (f_{C,x}(t, r_{SMS}), f_{C,y}(t, r_{SMS}), f_{C,z}(t, r_{SMS}))).
3. Determining a slice-specific additional compensation moment along the slice axis for each of the simultaneously excited slices with a reference point at r_{S}:

$${M}_{C , s} = ( \underline{T} {G}^{2} \int dt ( {f}_{C} ( t , {r}_{s} ) - {f}_{C} ( t , {r}_{SMS} ) ) ) {e}_{S}$$

Herein, the rotation matrix T of physical coordinates (x, y, z) rotates in logical imaging coordinates (frequency-encoding, phase-encoding, slice-encoding), and e_{S} is the unit vector along the direction of the slice encoding.
4. Determining temporal displacements of simultaneously applied RF pulses for the individual slice excitations such that for the slice s, the compensation moment M_{C,s} is generated.
5. Carrying out the scan with the compensation gradients G_{C}(t, r_{SMS}) and the calculated temporal displacements.

The calculations needed for this are time-consuming. It is proposed to accelerate a method of this type in that, in step 3 (determining a slice-specific additional compensation moment along the slice axis for each of the simultaneously excited slices with a reference point at rₛ), pre-calculated values are used. In this way, a real-time demand placed upon the scan execution is thus easier to fulfil.

What is decisive therein is the recognition that all the compensation gradients can be represented as the summation of terms of the same structure (characteristics):

$${G}_{C} ( t , r ) = {G}^{2} ( {f}_{C , x} ( t , r ) , {f}_{C , y} ( t , r ) , {f}_{C , z} ( t , r ) )$$

$${f}_{C , x / y / z} ( t , r ) = {\sum }_{k} {a}_{k , x / y / z} ( {r}_{l ( k , x / y / z )} + {v}_{k , x / y / z} ) {f}_{i ( k , x / y / z} ( t ) {f}_{j ( k , x / y / z )} ( t )$$

Therein, the sum of all the terms k=1 . . . . K, a_{k,x/y/z} are index-dependent and axis-dependent constants, and l(k,x/y/z), i(k,x/y/z), j(k,x/y/z) assign a direction to each index for each axis of the compensation gradient. V_{k,x/y/z} represents a displacement (only relevant for asymmetrical coils). For example, for f_{C,x}(t, r):

$$k = 1 : {a}_{1 , x} = - {α}^{2} / {B}_{0} {v}_{1 , x} = {x}_{0} 1 ( 1 , x ) = x i ( 1 , x ) = z j ( 1 , x ) = z \to - {α}^{2} / {B}_{0} ( x + {x}_{0} ) {f}_{z} ( t ) {f}_{z} ( t )$$

$$k = 2 : {a}_{2 , x} = α / {B}_{0} {v}_{2 , x} = {z}_{0 x} 1 ( 2 , x ) = z i ( 2 , x ) = x j ( 2 , x ) = z \to α / {B}_{0} ( z + {z}_{0 x} ) {f}_{x} ( t ) {f}_{z} ( t )$$

These considerations permit the integrals of normalized products of the form Fᵢⱼ=∫dt fᵢ(t) fⱼ(t) where i, j∈{x, y, z} to be determined once during the scan preparation for non-trapezoidal waveforms and, for example, included by the loaded characteristics, during a scan execution, to be available for a rapid calculation of the slice-specific compensation moments, wherein the following can be written:

$${M}_{C , s} = ( \underline{T} {G}^{2} \int dt ( {f}_{C} ( t , {r}_{s} ) - {f}_{C} ( t , {r}_{SMS} ) ) ) {e}_{S} = ( \underline{T} G \int dt {f}_{C} ( t , {r}_{s} - {r}_{SMS} ) ) {e}_{S}$$

$${\sum }_{k} {a}_{k , x} ( {( r - {r}_{SMS} )}_{l ( k , x )} + {v}_{k , x} ) {f}_{i ( k , x )} ( t ) {f}_{j ( k , x )} ( t ) ) = ( \underline{T} {G}^{2} \int dt ( {\sum }_{k} {a}_{k , y} ( {( r - {r}_{SMS} )}_{l ( k , y )} + {v}_{k , y} ) \text{} {f}_{i ( k , y )} ( \text{} t ) \text{} {f}_{j ( k , y )} ( \text{} t ) ) ) \text{} \text{} {e}_{S} \text{} {\sum }_{k} {a}_{k , z} ( \text{} {( r - {r}_{SMS} )}_{l ( k , z )} + {v}_{k , z} ) {f}_{i ( k , z )} ( t ) {f}_{j ( k , z )} ( t ) )$$

$${\sum }_{k} {a}_{k , x} ( {( r - {r}_{SMS} )}_{l ( k , x )} + {v}_{k , x} ) {F}_{i ( k , x ) j ( k , x )} ) = ( \underline{T} {G}^{2} ( {\sum }_{k} {a}_{k , y} ( {( r - {r}_{SMS} )}_{l ( k , y )} + {v}_{k , y} ) \text{} {F}_{i ( k , y ) j ( k , y )} ) ) \text{} {e}_{S} \text{} {\sum }_{k} {a}_{k , z} ( \text{} {( r - {r}_{SMS} )}_{l ( k , z )} + {v}_{k , z} ) {F}_{i ( k , z ) j ( k , z )} )$$

The decisive point is the replacement of the time integrals with the pre-calculated values Fᵢⱼ included, for example, by the characteristics CGF. The time-consuming pre-calculation can take place without any time pressure during the scan preparation. In step 4 (determining temporal displacements of simultaneously applied RF pulses for the individual slice excitations), the compensation moments determined in this way along the slice axis in a known manner can be realized by way of individual temporal displacements of the simultaneously applied RF pulses for the individual slice excitations.

As stated before, it is decisive in an embodiment of non-trapezoidal diffusion gradients, that on each axis, the specified 0th gradient moment M=G ∫dt f(t) is realized with a high degree of accuracy (possibly taking account of compensation gradients, i.e. M(r_{M})=G∫dt f(t)−G²∫dt f_{C}(t,r_{M})). It should be noted that the accuracy of the settability of desired amplitudes can be restricted. For example, the DAC converter can represent only a limited number of values. It is also conceivable that, for technical reasons (for example, limited scope of data packets and runtime performance), a data transport layer in the scanning system only supports a lower accuracy in the representation of amplitude values. If the amplitude values of the non-trapezoidal diffusion or compensation gradients are now defined with high accuracy (for example, with double floating point precision), but applied with reduced accuracy (for example, single floating point or fixed point precision), the resulting 0th gradient moment can deviate from the target value, which leads directly to a signal loss.

In order to counteract this problem skillfully, the following pre-calculations are proposed:
1. If the non-trapezoidal waveforms are defined in logical imaging coordinates (frequency encoding, phase encoding, slice encoding): rotation in physical coordinates (x, y, z) with high precision, G′(t)=T G(t).
2. If an additional rotation according to a direction assignment (similarly to direction vectors in conventional diffusion imaging) and/or a scan with a particular b-value is intended: rotation and scaling of the waveforms according to the directional assignment and b-value with high precision, G″(t)=S R G′(t).
3. If Maxwell term corrections are to be carried out: calculation of compensation gradients in physical coordinates G_{C}(t) with high precision (based upon G″(t)).
4. Determining a corrected waveform G′″(t)=G″(t)−G_{C}(t) with high precision
5. If the corrected waveform is applied by the scanning system in logical imaging coordinates: rotation with high precision, G″″(t)=T⁻¹ G″′(t).
6. Moment-preserving transformation into a representation with low precision g″″(t), for example, according to an algorithm analogous to an algorithm mentioned above in relation to a moment-preserving reading-in of non-trapezoidal waveforms, which can be expressed as follows in pseudo-code: (pseudo-code; G[i] is the target amplitudes with high precision, g[i] is the actual values with low precision), assuming a fixed hardware time grid Tᵣₐₛₜₑᵣ:

```
∘ For (axis = x, y, z)
  ▪ M_{residual} = 0
  ▪ For (i = 0 ... N-1)
    ● M_{desired} = G[i] * Tᵣₐₛₜₑᵣ + M_{residual}
    ● G_{current} = M_{desired}/ Tᵣₐₛₜₑᵣ
    ● g[axis][i] = Round(G_{current}) // to reduced precision
    ● M_{residual} = M_{desired} − g[axis][i] * Tᵣₐₛₜₑᵣ
```

The sequence of steps in the pseudo-code can vary herein and step 2 can be carried out, for example, before step 1. Steps can be grouped together, for example, steps 1 and 2 can be combined (M=S R T and/or M′=S T R).

Summarizing, with the method provided, different advantages are achieved, whereby different problems, for example, “spoiling” (relevant for SE and STE encoding) and “Maxwell compensation” and “moment-preserving transformation” (both relevant for any desired encodings) can be considered independently of one another.

In particular, even before an execution of a scan for capturing diffusion-weighted scan data, pre-calculations can be carried out, in particular, for determining the values described above

$$\begin{matrix}{m}_{D , i} = \int dt {f}_{i} ( t ) & \begin{matrix}for each section DW 1 , DW 2 , \\ DW 3 of a waveform GF , and\end{matrix} \\ {\underline{F}}_{D , i} = \int dt {f}_{i} ( t ) {f}_{i}^{T} ( t ) & \begin{matrix}for each section DW 1 , DW 2 , \\ DW 3 of a waveform GF ,\end{matrix}\end{matrix}$$

which can each be included by loaded characteristics of the waveform GF.

During an execution of a scan on the basis of the characteristics
a. the values of |M_{D,i}|=|G M_{D,i}| for the actual amplitude G, which correlates with the achieved b-value, possibly including taking account of the actual rotation, can be calculated in a rapid and uncomplicated manner,
b. a spoil moment |M_{D,1}|>c M_{SP}, |M_{D,2}|≥c M_{SP} (SE: c=1, STE: c=2) can be checked,
   if the checked condition is not met, the following can take place:
      deactivation of the non-trapezoidal diffusion gradients,
      (SMS: deactivation of temporal RF pulse shifts),
      activation of spoiler gradient pairs,
      (STE: activation of the additional spoiler gradients),
      continuation at d (application of the gradients).
   If the condition is met:
      deactivation of spoiler gradient pairs,
      activation of the non-trapezoidal diffusion gradients, (possibly including taking account of the actual rotation)
      determining Maxwell compensation gradients
         without SMS: reference position=slice position
         with SMS: reference position=mid-point of the SMS slices
         calculation of the non-trapezoidal compensation gradients (possibly including taking account of the actual rotation)
      (SMS: determining Maxwell compensation moments)
      (SMS: calculation of temporal RF pulse shifts for the slices)
      (STE: activation of the additional spoiler gradients)
      transformation der non-trapezoidal waveform
         addition of the compensation gradients to the diffusion gradients
         moment-preserving transformation of the corrected diffusion gradients (possibly after taking account of a coordinate transformation)
c. (SMS: calculation of the RF pulses with or without temporal shifts)
d. applying the activated gradients and the RF pulses

In the determination of implicit spoil moments, rotations of the non-trapezoidal gradient pulses (coordinate systems and/or direction assignments) can be taken into account. The rotated waveforms are obtained using a rotation matrix R as G′ᵢ(t)=G f′ᵢ(t)=R G′ᵢ(t)=G R fᵢ(t). The normalized 0th moments in rotated coordinates result from the pre-calculated moments of the original coordinates m_{D,i}=∫dt fᵢ(t) according to m′_{D,i}=∫dt f′ᵢ(t)=∫dt R fᵢ(t)=R ∫dt fᵢ(t)=R m_{D,i}. If for the checking of the spoil condition, the value of the implied spoil moment is taken into account, then |m′_{D,i}|=√(m′^{T}_{D,i} m′_{D,i})=√(R m_{D,i})^{T} (R m_{D,i})=√m^{T}_{D,i}R^{T}R m_{D,i}=|m_{D,i}| applies. The value of the spoil moment is invariant in relation to rotation (for rotation matrices, R^{T}=R⁻¹, so that R^{T}R=1) applies.

Maxwell field terms can be calculated in the manner described without restriction for symmetrical or asymmetrical gradient coils and compensated for locally. Similarly, the calculations and compensations can be carried out for magnets with horizontal orientation of the main field (parallel to the body axis of the patient) and with vertical orientation of the main field (perpendicularly to the body axis of the patient). For vertical field magnets (with which, for example, according to convention, the y-axis of the gradient coil extends along the direction of the main field), in the calculations it is only necessary to exchange the z and y-coordinates.

Rotations of the non-trapezoidal gradient pulses (for different direction assignments, similarly to the diffusion directions of conventional diffusion imaging) on determination of slice-specific compensation moments can be taken into account as follows. The waveform rotated with a rotation matrix R is given by G′(t)=G f′(t)=R G′(t)=G R f(t). The calculation of the corresponding compensation moments M′_{C,s}=(T G² ∫dt (f′_{C} (t, rₛ)−f′_{C} (t, r_{SMS}))) e_{S} ultimately requires the integrals of normalized products of the form F′ᵢⱼ=∫dt f′ᵢ(t) fⱼ(t) where i, j∈{x, y, z}. The auxiliary matrix H′(t)=f′(t) f′^{T}(t) contains in its nine elements H′ᵢⱼ(t) all the relevant products f′ᵢ(t) f′ⱼ(t) and allows the calculation of F′=∫dt H′(t). With H′(t)=f(t) f′^{T}(t)=(R f(t)) R f(t)^{T}=R f(t) f^{T}(t) R^{T}=R H(t) R^{T} it follows that F′=R ∫dt H(t) R^{T}=R F R^{T}: thus it is sufficient, during the scan execution, to rotate the pre-calculated values Fᵢⱼ in a matrix representation in order to determine the required values F′ᵢⱼ for the rotated waveforms.

For the same, non-trapezoidal gradient waveforms GF on all the axes Gₙ(t)=G f(t) vₙ with the direction vectors vₙ=(v_{n,x}, v_{n,y}, v_{n,z}), the elements of the b-matrix can be determined in the same way. Therein, a rotation matrix Rₙ can be determined in that it transforms a single axis gradient waveform adopted in the pre-calculation, for example, on the Gₓ-axis: Gₓ(t)=G f(t) (1, 0, 0), straight into the desired direction assignment of the diffusion direction:

$${G}_{n} ( t ) = {\underline{R}}_{n} = {G}_{x} ( t ) , where {R}_{n} = ( \begin{matrix}{v}_{n , x} , & {v}_{n , y ,} & {v}_{n , x} \\ 0 , & 0 , & 0 \\ 0 , & 0 , & 0\end{matrix} )$$

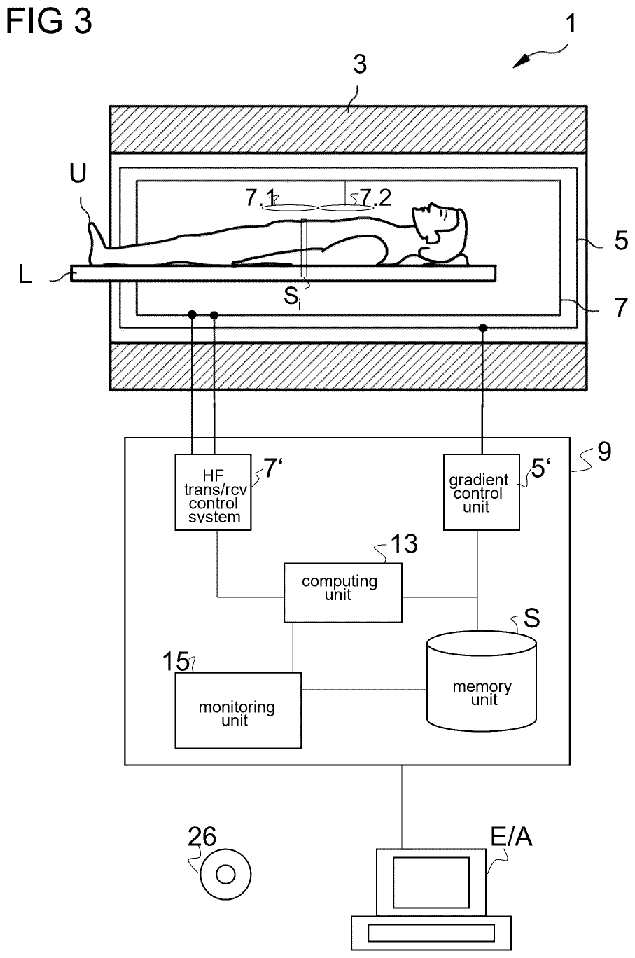

FIG. 3 schematically represents a magnetic resonance system 1 according to the disclosure. This comprises a magnet unit 3 for generating the main magnetic field, a gradient unit 5 for generating the gradient fields, a high frequency unit 7 for radiating-in and receiving high frequency signals, and a control facility 9 configured for carrying out a method according to the disclosure.

In FIG. 3, these subunits of the magnetic resonance system 1 are shown only in a coarse schematic form. The high frequency unit 7 can consist of a plurality of subunits and can comprise, for example, a plurality of coils. In particular, the high frequency unit 7 can comprise a body coil which is permanently integrated into the magnetic resonance system 1 and itself can comprise, for example, two antenna elements 7.1 and 7.2. Furthermore, the high frequency unit 7 can comprise one or a plurality of different local coils 7* that can be configured either only for transmitting high frequency signals or only for receiving the triggered high frequency signals or for both, and themselves can comprise a plurality of antenna elements and associated coil channels.

For investigation of an examination object U, for example, a patient or a phantom, said object can be introduced on a support L into the magnetic resonance system 1, in the scanning volume thereof. The slices S1 or S2 represent exemplary target volumes of the examination object from which echo signals can be recorded and captured as scan data.

The control facility 9 serves to control the magnetic resonance system 1 and can, in particular, control the gradient unit 5 by means of a gradient control system 5′ and the high frequency unit 7 by means of a high frequency transmitting/receiving control system 7′. The high frequency unit 7 can herein comprise a plurality of channels on which signals can be transmitted or received.

The high frequency unit 7 is responsible, together with its high frequency transmitting/receiving control system 7′ for the generation and radiating-in (transmission) of a high frequency alternating field for manipulation of the spins in a region to be manipulated (for example, in slices S to be scanned) of the examination object U. Herein, the middle frequency of the high frequency alternating field, also designated the B1 field, is typically adjusted so that, as far as possible, it lies close to the resonance frequency of the spin to be manipulated. Deviations of the middle frequency from the resonance frequency are referred to as off-resonance. In order to generate the B1 field, in the high frequency unit 7, currents controlled by means of the high frequency transmitting/receiving control system 7′ are applied to the RF coils.

Furthermore, the control facility 9 comprises a monitoring unit 15 for monitoring according to the disclosure of an executability of a capturing of diffusion-weighted scan values. The control facility 9 is configured overall to carry out a method according to the disclosure.

A computing unit 13 included by the control facility 9 is configured to carry out all the computation operations necessary for the required scans and determinations. Intermediate results and results needed for this or established herein can be stored in a memory unit S of the control facility 9. The units described are herein not necessarily to be understood as physically separate units, but merely represent a subdivision into units of purpose which, however, can also be realized, for example, in fewer, or even only in one single, physical unit.

Via an input/output facility E/A of the magnetic resonance system 1, for example, control commands can be passed, for example, by a user to the magnetic resonance system and/or results from the control facility 9, such as, for example, image data can be displayed.

A method described herein can also exist in the form of a computer program that comprises commands that carry out the described method on a control facility 9. Similarly, a computer-readable storage medium can be provided which comprises commands that, when executed by a control facility 9 of a magnetic resonance system 1, cause said control facility to carry out the method described.

Independent of the grammatical term usage, individuals with male, female, or other gender identities are included within the term.

1. A method for capturing diffusion-weighted scan data of an examination object with a magnetic resonance system, the method comprising:
a) loading a scan protocol to be used with scan parameters to be set and which include a desired non-trapezoidal gradient waveform for the diffusion encoding;
b) loading prepared characteristics for at least the non-trapezoidal gradient waveform;
c) assigning possible parameter values of at least one scan parameter of the scan protocol to be set to at least one category providing an executability of the scan protocol on the magnetic resonance system based on the loaded characteristics;
d) inputting at least one desired parameter value of at least one scan parameter of the scan protocol taking into account of the assignment;
e) if a parameter value has not yet been input for each scan parameter to carry out the scan protocol, repeating steps c) and d), at least for scan parameters for which no parameter value has yet been input, until parameter values with which the scan protocol is to be carried out are input; and
f) capturing diffusion-weighted scan data using the scan protocol with the input parameter values.

1. The method as claimed in claim 1, wherein the non-trapezoidal gradient waveform is defined along at least one axis of a coordinate system, and a predetermined scaling factor is assigned to a direction of the at least one axis of the coordinate system.

2. The method as claimed in claim 1, wherein the scan parameters to be set comprise spoiler gradients.

4. The method as claimed in claim 1, wherein the scan parameters to be set comprise compensation gradients.

5. The method as claimed in claim 1, wherein the scan parameters to be set comprise gradient amplitudes.

6. The method as claimed in claim 1, wherein the desired non-trapezoidal gradient waveform is selected from a plurality of non-trapezoidal gradient waveforms and is loaded as a description of the respective non-trapezoidal gradient waveform that is disassembled into at least one section that is stored individually or together in a file.

7. The method as claimed in claim 6, wherein the description represents the non-trapezoidal gradient waveform as piecewise constant.

8. The method as claimed in claim 1, wherein a zeroth moment of a desired non-trapezoidal gradient waveform is checked before and/or during a capturing of diffusion-weighted scan data and, if the checking reveals a deviation from a target value, a gradient amplitude of the non-trapezoidal gradient waveform is corrected to compensate for the deviation.

9. A magnetic resonance system, comprising:
a magnet unit;
a gradient unit;
a high frequency unit; and
a control apparatus including a high frequency transmitting/receiving control system and a monitoring unit, and configured to carry out a method as claimed in claim 1 on the magnetic resonance system.

10. A non-transitory computer-readable storage medium comprising commands which, on execution by a control apparatus of a magnetic resonance system, cause the control apparatus to carry out the method as claimed in claim 1.
